(19) United States
(12) Patent Application Publication
(10) Pub. No.: US 2023/0229087 A1
(43) Pub. Date: Jul. 20, 2023

(54) UV-CURABLE QUANTUM DOT FORMULATIONS

(71) Applicant: Nanosys, Inc., Milpitas, CA (US)

(72) Inventors: Christian IPPEN, Cupertino, CA (US); Diego BARRERA, San Jose, CA (US); Ruiqing MA, Morristown, NJ (US)

(73) Assignee: Nanosys, Inc., Milpitas, CA (US)

(21) Appl. No.: 18/098,167

(22) Filed: Jan. 18, 2023

Related U.S. Application Data
(60) Provisional application No. 63/300,948, filed on Jan. 19, 2022.

(51) Int. Cl. G03F 7/20; H10K 50/115; G03F 7/029; G03F 7/004; G03F 7/16; G03F 7/32; H10K 71/20

(52) U.S. Cl. CPC G03F 7/2004; H10K 50/115; G03F 7/029; G03F 7/0048; G03F 7/16; G03F 7/325; H10K 71/233

(57) ABSTRACT

Provided are patterned films comprising nanostructures and one or more UV-cured monomers. Also provide are methods of making the patterned films, and electroluminescent devices comprising the patterned films.

### FIELD OF THE INVENTION

The invention is in the field of nanostructures. Provided are patterned films comprising nanostructures and one or more UV-cured monomers.

### BRIEF SUMMARY OF THE INVENTION

Provided are ultraviolet (UV)-cured patterned films deposited on a substrate comprising from about 60 wt % to about 95 wt % nanostructures and one or more UV-cured monomers.

In some embodiments, the one or more UV-cured monomers are poly(methyl (meth)acrylate), poly(ethylene glycol phenyl (meth)acrylate), poly(di(ethylene glycol) methyl ether (meth)acrylate), poly(diethylene glycol monoethyl ether acrylate), poly(ethylene glycol methyl ether (meth)acrylate), poly(1,3-butylene glycol di(meth)acrylate), poly(polyethylene glycol di(meth)acrylate), poly(1,6-hexanediol diacrylate), poly(isobornyl acrylate), poly(tetrahydrofurfuryl acrylate), poly(lauryl acrylate), poly(tricyclodecane dimethanol diacrylate), poly(glycerol triacrylate), poly(1,1,1-trimethylolpropane triacrylate), poly(pentaerythritol tetraacrylate), poly(bistrimethylolpropane tetraacrylate), poly(dipentaerythritol pentaacrylate), poly(pentaerythritol triacrylate), poly(pentaerythritol tetracrylate), poly(trimethylolpropane triacrylate), poly(dipentaerythritol pentaacrylate ester), poly(isobornyl methacrylate), poly(tetrahydrofurfuryl methacrylate), poly(lauryl methacrylate), poly(tricyclodecane dimethanol dimethacrylate), poly(glycerol trimethacrylate), poly(1,1,1-trimethylolpropane trimethacrylate), poly(pentaerythritol tetramethacrylate), poly(bistrimethylolpropane tetramethacrylate), poly(dipentaerythritol pentamethacrylate), poly(pentaerythritol trimethacrylate), poly(pentaerythritol tetramethcrylate), poly(trimethylolpropane trimethacrylate), poly(dipentaerythritol pentamethacrylate ester), poly(1,6-hexanediol dimethacrylate), poly(1,4-butanediol diacrylate), poly(1,9-nonanediol diacrylate), poly(1,4-butanediol dimethacrylate), poly(1,9-nonanediol dimethacrylate), or combinations thereof.

In some embodiments, the film further comprises one or more photoinitiators.

In some embodiments, the film is produced by:

(a) depositing onto the substrate a solution comprising the nanostructures, one or more UV-curable monomers, a photoinitiator, and one or more solvents, wherein the weight ratio of the nanostructures to the one or more UV-curable monomers is from about 20:1 to about 1.5:1;

(b) evaporating the one or more solvents to give a film comprising the nanostructures, one or more UV-curable monomers, and a photoinitiator;

(c) applying a photomask to the substrate;

(d) irradiating the substrate with ultraviolet radiation; (e) removing the photomask; and

(f) washing the substrate with one or more solvents to provide the patterned film.

In some embodiments, the weight ratio of the nanostructures to the one or more UV-curable monomers is from about 14:1 to about 6:1.

In some embodiments, the one or more UV-curable monomers are acrylate monomers.

In some embodiments, the acrylate monomer is 1,6-hexanediol diacrylate.

In some embodiments, the film obtained in (b) comprises from about 0.1 wt % to about 0.3 wt % photoinitiator relative to the total weight of the one of more UV-curable monomers.

In some embodiments, the photoinitiator is ethyl phenyl(2,4,6-trimethylbenzoyl)phosphinate (TPO-L).

In some embodiments, the irradiating in (d) is a dose of about 530 mJ/cm² of 365 nm ultraviolet radiation.

In some embodiments, the one or more solvents is toluene.

In some embodiments, the nanostructures are quantum dots.

In some embodiments, the nanostructures comprises polyethylene glycol-based ligands.

In some embodiments, the film is insoluble in toluene.

In some embodiments, the film has a quantum yield (QY) of from about 35% to about 50%.

Also provided are electroluminescent devices comprising the films described above.

In some embodiments, the device has a maximum external quantum efficiency (EQE) of from about 3.75% to about 5.25%.

In some embodiments, the device has a maximum luminance of from about 4,000 cd/m² to about 9,000 cd/m².

In some embodiments, the device has a lifetime at 1,000 nits of from about 8.5 h to about 20.5 h.

In some embodiments, the device has a lifetime at 100 nits of from about 500 h to about 1,300 h.

In some embodiments, the film pattern is a pixel pattern.

### BRIEF DESCRIPTION OF THE DRAWINGS

The accompanying drawings, which are incorporated herein and form part of the specification, illustrate the present embodiments and, together with the description, further serve to explain the principles of the present embodiments and to enable a person skilled in the relevant art(s) to make and use the present embodiments.

FIGS. 1A and 1B are two line graphs showing current density as a function of voltage for electroluminescent devices comprising thinner (FIG. 1A) and thicker (FIG. 1B) emissive layers, the emissive layers comprising ultraviolet (UV)-cured quantum dot (QD) films with varying amounts of 1,6-hexanediol diacrylate (HDDA).

FIG. 2 is a scheme depicting the a network of polymerized HDDA formed around QDs in a close-packed emissive layer (EML).

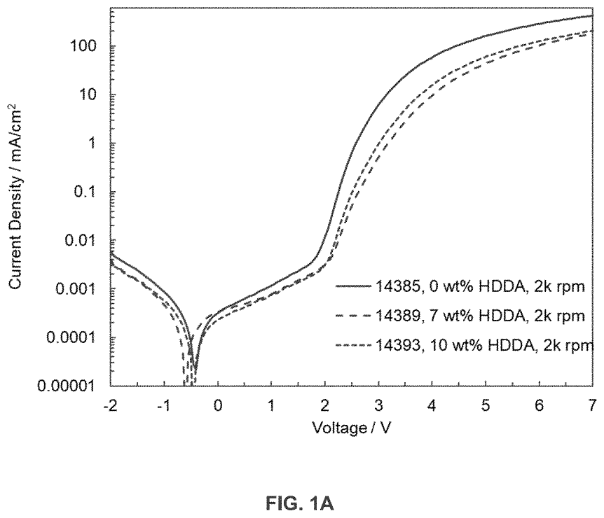

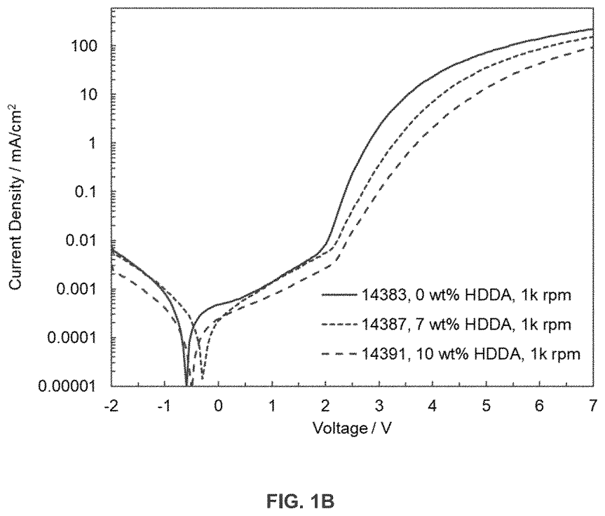

### DETAILED DESCRIPTION OF THE INVENTION

Unless defined otherwise, all technical and scientific terms used herein have the same meaning as commonly understood by one of ordinary skill in the art to which the invention pertains. The following definitions supplement those in the art and are directed to the current application and are not to be imputed to any related or unrelated case, e.g., to any commonly owned patent or application. Although any methods and materials similar or equivalent to those described herein can be used in practice for testing, the preferred materials and methods are described herein. Accordingly, the terminology used herein is for the purpose of describing particular embodiments only, and is not intended to be limiting.

As used in this specification and the appended claims, the singular forms “a,” “an,” and “the” include plural referents unless the context clearly dictates otherwise. Thus, for example, reference to “a nanostructure” includes a plurality of such nanostructures, and the like.

The term “about” as used herein indicates the value of a given quantity varies by ±10% of the value. For example, “about 100 nm” encompasses a range of sizes from 90 nm to 110 nm, inclusive.

A “nanostructure” is a structure having at least one region or characteristic dimension with a dimension of less than about 500 nm. In some embodiments, the nanostructure has a dimension of less than about 200 nm, less than about 100 nm, less than about 50 nm, less than about 20 nm, or less than about 10 nm, e.g., 1-10 nm. Typically, the region or characteristic dimension will be along the smallest axis of the structure. Examples of such structures include nanowires, nanorods, nanotubes, branched nanostructures, nanotetrapods, tripods, bipods, nanocrystals, nanodots, quantum dots, nanoparticles, and the like. Nanostructures can be, e.g., substantially crystalline, substantially monocrystalline, polycrystalline, amorphous, or a combination thereof. In some embodiments, each of the three dimensions of the nanostructure has a dimension of less than about 500 nm, less than about 200 nm, less than about 100 nm, less than about 50 nm, less than about 20 nm, or less than about 10 nm.

The term “heterostructure” when used with reference to nanostructures refers to nanostructures characterized by at least two different and/or distinguishable material types. Typically, one region of the nanostructure comprises a first material type, while a second region of the nanostructure comprises a second material type. In certain embodiments, the nanostructure comprises a core of a first material and at least one shell of a second (or third etc.) material, where the different material types are distributed radially about the long axis of a nanowire, a long axis of an arm of a branched nanowire, or the center of a nanocrystal, for example. A shell can but need not completely cover the adjacent materials to be considered a shell or for the nanostructure to be considered a heterostructure; for example, a nanocrystal characterized by a core of one material covered with small islands of a second material is a heterostructure. In other embodiments, the different material types are distributed at different locations within the nanostructure; e.g., along the major (long) axis of a nanowire or along a long axis of arm of a branched nanowire. Different regions within a heterostructure can comprise entirely different materials, or the different regions can comprise a base material (e.g., silicon) having different dopants or different concentrations of the same dopant.

As used herein, the “diameter” of a nanostructure refers to the diameter of a cross-section normal to a first axis of the nanostructure, where the first axis has the greatest difference in length with respect to the second and third axes (the second and third axes are the two axes whose lengths most nearly equal each other). The first axis is not necessarily the longest axis of the nanostructure; e.g., for a disk-shaped nanostructure, the cross-section would be a substantially circular cross-section normal to the short longitudinal axis of the disk. Where the cross-section is not circular, the diameter is the average of the major and minor axes of that cross-section. For an elongated or high aspect ratio nanostructure, such as a nanowire, the diameter is measured across a cross-section perpendicular to the longest axis of the nanowire. For a spherical nanostructure, the diameter is measured from one side to the other through the center of the sphere.

The terms “crystalline” or “substantially crystalline,” when used with respect to nanostructures, refer to the fact that the nanostructures typically exhibit long-range ordering across one or more dimensions of the structure. It will be understood by one of skill in the art that the term “long range ordering” will depend on the absolute size of the specific nanostructures, as ordering for a single crystal cannot extend beyond the boundaries of the crystal. In this case, “long-range ordering” will mean substantial order across at least the majority of the dimension of the nanostructure. In some instances, a nanostructure can bear an oxide or other coating, or can be comprised of a core and at least one shell. In such instances it will be appreciated that the oxide, shell(s), or other coating can but need not exhibit such ordering (e.g. it can be amorphous, polycrystalline, or otherwise). In such instances, the phrase “crystalline,” “substantially crystalline,” “substantially monocrystalline,” or “monocrystalline” refers to the central core of the nanostructure (excluding the coating layers or shells). The terms “crystalline” or “substantially crystalline” as used herein are intended to also encompass structures comprising various defects, stacking faults, atomic substitutions, and the like, as long as the structure exhibits substantial long range ordering (e.g., order over at least about 80% of the length of at least one axis of the nanostructure or its core). In addition, it will be appreciated that the interface between a core and the outside of a nanostructure or between a core and an adjacent shell or between a shell and a second adjacent shell may contain non-crystalline regions and may even be amorphous. This does not prevent the nanostructure from being crystalline or substantially crystalline as defined herein.

The term “monocrystalline” when used with respect to a nanostructure indicates that the nanostructure is substantially crystalline and comprises substantially a single crystal. When used with respect to a nanostructure heterostructure comprising a core and one or more shells, “monocrystalline” indicates that the core is substantially crystalline and comprises substantially a single crystal.

A “nanocrystal” is a nanostructure that is substantially monocrystalline. A nanocrystal thus has at least one region or characteristic dimension with a dimension of less than about 500 nm. In some embodiments, the nanocrystal has a dimension of less than about 200 nm, less than about 100 nm, less than about 50 nm, less than about 20 nm, or less than about 10 nm, e.g., 1-10 nm. The term “nanocrystal” is intended to encompass substantially monocrystalline nanostructures comprising various defects, stacking faults, atomic substitutions, and the like, as well as substantially monocrystalline nanostructures without such defects, faults, or substitutions. In the case of nanocrystal heterostructures comprising a core and one or more shells, the core of the nanocrystal is typically substantially monocrystalline, but the shell(s) need not be. In some embodiments, each of the three dimensions of the nanocrystal has a dimension of less than about 500 nm, less than about 200 nm, less than about 100 nm, less than about 50 nm, less than about 20 nm, or less than about 10 nm.

The term “quantum dot” (or “dot”) refers to a nanocrystal that exhibits quantum confinement or exciton confinement. Quantum dots can be substantially homogenous in material properties, or in certain embodiments, can be heterogeneous, e.g., including a core and at least one shell. The optical properties of quantum dots can be influenced by their particle size, chemical composition, and/or surface composition, and can be determined by suitable optical testing available in the art. The ability to tailor the nanocrystal size, e.g., in the range between about 1 nm and about 15 nm, enables photoemission coverage in the entire optical spectrum to offer great versatility in color rendering.

A “ligand” is a molecule capable of interacting (whether weakly or strongly) with one or more facets of a nanostructure, e.g., through covalent, ionic, van der Waals, or other molecular interactions with the surface of the nanostructure.

“Photoluminescence quantum yield” (PLQY) is the ratio of photons emitted to photons absorbed, e.g., by a nanostructure or population of nanostructures. As known in the art, quantum yield is typically determined by a comparative method using well-characterized standard samples with known quantum yield values.

“Peak emission wavelength” (PWL) is the wavelength where the radiometric emission spectrum of the light source reaches its maximum.

As used herein, the term “shell” refers to material deposited onto the core or onto previously deposited shells of the same or different composition and that result from a single act of deposition of the shell material. The exact shell thickness depends on the material as well as the precursor input and conversion and can be reported in nanometers or monolayers. As used herein, “target shell thickness” refers to the intended shell thickness used for calculation of the required precursor amount. As used herein, “actual shell thickness” refers to the actually deposited amount of shell material after the synthesis and can be measured by methods known in the art. By way of example, actual shell thickness can be measured by comparing particle diameters determined from transmission electron microscopy (TEM) images of nanocrystals before and after a shell synthesis.

As used herein, the term “full width at half-maximum” (FWHM) is a measure of the size distribution of nanoparticles. The emission spectra of nanoparticles generally have the shape of a Gaussian curve. The width of the Gaussian curve is defined as the FWHM and gives an idea of the size distribution of the particles. A smaller FWHM corresponds to a narrower quantum dot nanocrystal size distribution. FWHM is also dependent upon the peak emission wavelength.

As used herein, the term “half width at half-maximum” (HWHM) is a measure of the size distribution of nanoparticles extracted from UV-vis spectroscopy curves. A HWHM on the low-energy side of the first exciton absorption peak can be used as a suitable indicator of the size distribution, with smaller HWHM values corresponding to narrower size distributions.

### Nanostructure Core

The nanostructures cores for use in the present invention can be produced from any suitable material, suitably an inorganic material, and more suitably an inorganic conductive or semiconductive material. Suitable semiconductor materials include any type of semiconductor, including Group II-VI, Group III-V, Group IV-VI, and Group IV semiconductors. Suitable semiconductor materials include, but are not limited to, Si, Ge, Sn, Se, Te, B, C (including diamond), P, BN, BP, BAs, AlN, AlP, AlAs, AlSb, GaN, GaP, GaAs, GaSb, InN, InP, InAs, InSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, Al₂CO, and combinations thereof.

The synthesis of Group II-VI nanostructures has been described in U.S. Pat. Nos. 6,225,198, 6,322,901, 6,207,229, 6,607,829, 6,861,155, 7,060,243, 7,125,605, 7,374,824, 7,566,476, 8,101,234, and 8,158,193 and in U.S. Patent Appl. Publication Nos. 2011/0262752 and 2011/0263062. In some embodiments, the core is a Group II-VI nanocrystal selected from the group consisting of ZnO, ZnSe, ZnS, ZnTe, CdO, CdSe, CdS, CdTe, HgO, HgSe, HgS, and HgTe. In some embodiments, the core is a nanocrystal selected from the group consisting of ZnSe, ZnS, CdSe, and CdS.

Although Group II-VI nanostructures such as CdSe and CdS quantum dots can exhibit desirable luminescence behavior, issues such as the toxicity of cadmium limit the applications for which such nanostructures can be used. Less toxic alternatives with favorable luminescence properties are thus highly desirable. Group III-V nanostructures in general and InP-based nanostructures in particular, offer the best known substitute for cadmium-based materials due to their compatible emission range.

Synthesis of InP-based nanostructures has been described, e.g., in Xie, R., et al., “Colloidal InP nanocrystals as efficient emitters covering blue to near-infrared,” J. Am. Chem. Soc. 129:15432-15433 (2007); Micic, O. I., et al., “Core-shell quantum dots of lattice-matched ZnCdSe2 shells on InP cores: Experiment and theory,” J. Phys. Chem. B 104:12149-12156 (2000); Liu, Z., et al., “Coreduction colloidal synthesis of III-V nanocrystals: The case of InP,” Angew. Chem. Int. Ed. Engl. 47:3540-3542 (2008); Li, L. et al., “Economic synthesis of high quality InP nanocrystals using calcium phosphide as the phosphorus precursor,” Chem. Mater. 20:2621-2623 (2008); D. Battaglia and X. Peng, “Formation of high quality InP and InAs nanocrystals in a noncoordinating solvent,” Nano Letters 2:1027-1030 (2002); Kim, S., et al., “Highly luminescent InP/GaP/ZnS nanocrystals and their application to white light-emitting diodes,” J. Am. Chem. Soc. 134:3804-3809 (2012); Nann, T., et al., “Water splitting by visible light: A nanophotocathode for hydrogen production,” Angew. Chem. Int. Ed. 49:1574-1577 (2010); Borchert, H., et al., “Investigation of ZnS passivated InP nanocrystals by XPS,” Nano Letters 2:151-154 (2002); L. Li and P. Reiss, “One-pot synthesis of highly luminescent InP/ZnS nanocrystals without precursor injection,” J. Am. Chem. Soc. 130:11588-11589 (2008); Hussain, S., et al. “One-pot fabrication of high-quality InP/ZnS (core/shell) quantum dots and their application to cellular imaging,” Chemphyschem. 10:1466-1470 (2009); Xu, S., et al., “Rapid synthesis of high-quality InP nanocrystals,” J. Am. Chem. Soc. 128:1054-1055 (2006); Micic, O. I., et al., “Size-dependent spectroscopy of InP quantum dots,” J. Phys. Chem. B 101:4904-4912 (1997); Haubold, S., et al., “Strongly luminescent InP/ZnS core-shell nanoparticles,” Chemphyschem. 5:331-334 (2001); CrosGagneux, A., et al., “Surface chemistry of InP quantum dots: A comprehensive study,” J. Am. Chem. Soc. 132:18147-18157 (2010); Micic, O. I., et al., “Synthesis and characterization of InP, GaP, and GalnP2 quantum dots,” J. Phys. Chem. 99:7754-7759 (1995); Guzelian, A.A., et al., “Synthesis of size-selected, surface-passivated InP nanocrystals,” J. Phys. Chem. 100:7212-7219 (1996); Lucey, D.W., et al., “Monodispersed InP quantum dots prepared by colloidal chemistry in a non-coordinating solvent,” Chem. Mater. 17:3754-3762 (2005); Lim, J., et al., “InP@ZnSeS, core@composition gradient shell quantum dots with enhanced stability,” Chem. Mater. 23:4459-4463 (2011); and Zan, F., et al., “Experimental studies on blinking behavior of single InP/ZnS quantum dots: Effects of synthetic conditions and UV irradiation,” J. Phys. Chem. C 116:394-3950 (2012). However, such efforts have had only limited success in producing InP nanostructures with high quantum yields.

In some embodiments, the InP core is doped. In some embodiments, the dopant of the nanocrystal core comprises a metal, including one or more transition metals. In some embodiments, the dopant is a transition metal selected from the group consisting of Ti, Zr, Hf, V, Nb, Ta, Cr, Mo, W, Mn, Tc, Re, Fe, Ru, Os, Co, Rh, Ir, Ni, Pd, Pt, Cu, Ag, Au, and combinations thereof. In some embodiments, the dopant comprises a non-metal. In some embodiments, the dopant is ZnS, ZnSe, ZnTe, CdSe, CdS, CdTe, HgS, HgSe, HgTe, CuInS2, CuInSe2, AlN, AlP, AlAs, GaN, GaP, or GaAs.

In some embodiments, the core is purified before deposition of a shell. In some embodiments, the core is filtered to remove precipitate from the core solution.

In some embodiments, the diameter of the InP core is determined using quantum confinement. Quantum confinement in zero-dimensional nanocrystallites, such as quantum dots, arises from the spatial confinement of electrons within the crystallite boundary. Quantum confinement can be observed once the diameter of the material is of the same magnitude as the de Broglie wavelength of the wave function. The electronic and optical properties of nanoparticles deviate substantially from those of bulk materials. A particle behaves as if it were free when the confining dimension is large compared to the wavelength of the particle. During this state, the bandgap remains at its original energy due to a continuous energy state. However, as the confining dimension decreases and reaches a certain limit, typically in nanoscale, the energy spectrum becomes discrete. As a result, the bandgap becomes size-dependent.

In some embodiments, the nanostructures are free from cadmium. As used herein, the term “free of cadmium” is intended that the nanostructures contain less than 100 ppm by weight of cadmium. The Restriction of Hazardous Substances (RoHS) compliance definition requires that there must be no more than 0.01% (100 ppm) by weight of cadmium in the raw homogeneous precursor materials. The cadmium level in the Cd-free nanostructures of the present invention is limited by the trace metal concentration in the precursor materials. The trace metal (including cadmium) concentration in the precursor materials for the Cd-free nanostructures, can be measured by inductively coupled plasma mass spectroscopy (ICP-MS) analysis, and are on the parts per billion (ppb) level. In some embodiments, nanostructures that are “free of cadmium” contain less than about 50 ppm, less than about 20 ppm, less than about 10 ppm, or less than about 1 ppm of cadmium.

### Shells

In some embodiments, the nanostructure cores comprise one or more shells.

Exemplary materials for preparing shells include, but are not limited to, Si, Ge, Sn, Se, Te, B, C (including diamond), P, Co, Au, BN, BP, BAs, AlN, AlP, AlAs, AlSb, GaN, GaP, GaAs, GaSb, InN, InP, InAs, InSb, GaSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, Al₂CO₃ and combinations thereof.

In some embodiments, the shell is a mixture of at least two of a zinc source, a selenium source, a sulfur source, a tellurium source, and a cadmium source. In some embodiments, the shell is a mixture of two of a zinc source, a selenium source, a sulfur source, a tellurium source, and a cadmium source. In some embodiments, the shell is a mixture of three of a zinc source, a selenium source, a sulfur source, a tellurium source, and a cadmium source. In some embodiments, the shell is a mixture of: zinc and sulfur; zinc and selenium; zinc, sulfur, and selenium; zinc and tellurium; zinc, tellurium, and sulfur; zinc, tellurium, and selenium; zinc, cadmium, and sulfur; zinc, cadmium, and selenium; cadmium and sulfur; cadmium and selenium; cadmium, selenium, and sulfur; cadmium and zinc; cadmium, zinc, and sulfur; cadmium, zinc, and selenium; or cadmium, zinc, sulfur, and selenium. In some embodiments, the shell is a mixture of zinc and selenium. In some embodiments, the shell is a mixture of zinc and sulfur.

Exemplary core/shell luminescent nanostructures include, but are not limited to, (represented as core/shell) CdSe/ZnSe and InP/ZnSe.

In some embodiments, the shell comprises ZnSe. The thickness of the shell can be controlled by varying the amount of precursor provided. For a given shell thickness, at least one of the precursors is optionally provided in an amount whereby, when a growth reaction is substantially complete, a shell of a predetermined thickness is obtained. In some embodiments, the molar ratio of the zinc source and the selenium source is between about 0.01:1 and about 1:1.5, about 0.01:1 and about 1:1.25, about 0.01:1 and about 1:1, about 0.01:1 and about 1:0.75, about 0.01:1 and about 1:0.5, about 0.01:1 and about 1:0.25, about 0.01:1 and about 1:0.05, about 0.05:1 and about 1:1.5, about 0.05:1 and about 1:1.25, about 0.05:1 and about 1:1, about 0.05:1 and about 1:0.75, about 0.05:1 and about 1:0.5, about 0.05:1 and about 1:0.25, about 0.25:1 and about 1:1.5, about 0.25:1 and about 1:1.25, about 0.25:1 and about 1:1, about 0.25:1 and about 1:0.75, about 0.25:1 and about 1:0.5, about 0.5:1 and about 1:1.5, about 0.5:1 and about 1:1.25, about 0.5:1 and about 1:1, about 0.5:1 and about 1:0.75, about 0.75:1 and about 1:1.5, about 0.75:1 and about 1:1.25, about 0.75:1 and about 1:1, about 1:1 and about 1:1.5, about 1:1 and about 1:1.25, or about 1:1.25 and about 1:1.5.

The thickness of the ZnSe shell layer can be controlled by varying the amount of zinc and selenium sources provided and/or by use of longer reaction times and/or higher temperatures. At least one of the sources is optionally provided in an amount whereby, when a growth reaction is substantially complete, a layer of a predetermined thickness is obtained.

The thickness of the ZnSe thin shell can be determined using techniques known to those of skill in the art. In some embodiments, the thickness of the inner thin shell is determined by comparing the average diameter of the nanostructure before and after the addition of the inner thin shell. In some embodiments, the average diameter of the nanostructure before and after the addition of the inner thin shell is determined by TEM. In some embodiments, the ZnSe shell has a thickness of between about 0.01 nm and about 0.35 nm, about 0.01 nm and about 0.3 nm, about 0.01 nm and about 0.25 nm, about 0.01 nm and about 0.2 nm, about 0.01 nm and about 0.1 nm, about 0.01 nm and about 0.05 nm, about 0.05 nm and about 0.35 nm, about 0.05 nm and about 0.3 nm, about 0.05 nm and about 0.25 nm, about 0.05 nm and about 0.2 nm, about 0.05 nm and about 0.1 nm, about 0.1 nm and about 0.35 nm, about 0.1 nm and about 0.3 nm, about 0.1 nm and about 0.25 nm, about 0.1 nm and about 0.2 nm, about 0.2 nm and about 0.35 nm, about 0.2 nm and about 0.3 nm, about 0.2 nm and about 0.25 nm, about 0.25 nm and about 0.35 nm, about 0.25 nm and about 0.3 nm, or about 0.3 nm and about 0.35 nm.

In some embodiments, the zinc source is a dialkyl zinc compound. In some embodiments, the zinc source is a zinc carboxylate. In some embodiments, the zinc source is diethylzinc, dimethylzinc, zinc acetate, zinc acetylacetonate, zinc iodide, zinc bromide, zinc chloride, zinc fluoride, zinc carbonate, zinc cyanide, zinc nitrate, zinc oleate, zinc oxide, zinc peroxide, zinc perchlorate, zinc sulfate, zinc hexanoate, zinc octanoate, zinc laurate, zinc myristate, zinc palmitate, zinc stearate, zinc dithiocarbamate, or mixtures thereof. In some embodiments, the zinc source is zinc oleate, zinc hexanoate, zinc octanoate, zinc laurate, zinc myristate, zinc palmitate, zinc stearate, zinc dithiocarbamate, or mixtures thereof. In some embodiments, the zinc source is zinc oleate.

In some embodiments, the selenium source is an alkyl-substituted selenourea. In some embodiments, the selenium source is a phosphine selenide. In some embodiments, the selenium source is selected from trioctylphosphine selenide, tri(n-butyl)phosphine selenide, tri(sec-butyl)phosphine selenide, tri(tert-butyl)phosphine selenide, trimethylphosphine selenide, triphenylphosphine selenide, diphenylphosphine selenide, phenylphosphine selenide, tricyclohexylphosphine selenide, cyclohexylphosphine selenide, 1-octaneselenol, 1-dodecaneselenol, selenophenol, elemental selenium, hydrogen selenide, bis(trimethylsilyl) selenide, selenourea, and mixtures thereof In some embodiments, the selenium source is tri(n-butyl)phosphine selenide, tri(sec-butyl)phosphine selenide, or tri(tert-butyl)phosphine selenide. In some embodiments, the selenium source is trioctylphosphine selenide.

In some embodiments, the ZnSe shell is synthesized in the presence of at least one nanostructure ligand. Ligands can, e.g., enhance the miscibility of nanostructures in solvents or polymers (allowing the nanostructures to be distributed throughout a composition such that the nanostructures do not aggregate together), increase quantum yield of nanostructures, and/or preserve nanostructure luminescence (e.g., when the nanostructures are incorporated into the UV-cured monomers). In some embodiments, the ligand(s) for the InP core synthesis and for the shell synthesis are the same. In some embodiments, the ligand(s) for the core synthesis and for the shell synthesis are different. Following synthesis, any ligand on the surface of the nanostructures can be exchanged for a different ligand with other desirable properties. Examples of ligands are disclosed in U.S. Pat. Nos. 7,572,395, 8,143,703, 8,425,803, 8,563,133, 8,916,064, 9,005,480, 9,139,770, and 9,169,435, and in U.S. Patent Application Publication No. 2008/0118755.

Ligands suitable for the synthesis of a shell are known by those of skill in the art.

In some embodiments, the ligand is a fatty acid selected from the group consisting of lauric acid, caproic acid, myristic acid, palmitic acid, stearic acid, and oleic acid. In some embodiments, the ligand is an organic phosphine or an organic phosphine oxide selected from trioctylphosphine oxide (TOPO), trioctylphosphine (TOP), diphenylphosphine (DPP), triphenylphosphine oxide, and tributylphosphine oxide. In some embodiments, the ligand is an amine selected from the group consisting of dodecylamine, oleylamine, hexadecylamine, dioctylamine, and octadecylamine. In some embodiments, the ligand is oleic acid.

In some embodiments, the nanostructure composition comprises InP/ZnSe/ZnS core-shell nanostructures, wherein the thickness of at least one of the ZnSe and ZnS shells is between 0.7 nm and 3.5 nm, wherein the nanostructures exhibit a photoluminescence quantum yield of 60-99%, wherein the nanostructures exhibit a full width half maximum of 35 nm to 45 nm; and wherein the nanostructures exhibit an OD_{450/}peak of about 1.0 to about 3.0. Such nanostructures and methods of making are disclosed in U.S. Appl. Publ. Nos. 2017/0306227 and 20180199007.

In some embodiments, the nanostructures comprising a core comprising indium phosphide and at least two shells, wherein at least one of the shells comprises zinc, wherein the nanostructure displays a photoluminescence quantum yield between about 94% and about 100%, and a wherein the nanostructure has a full width at half-maximum of less than 45 nm. In some embodiments, the nanostructures are InP/ZnSe/ZnS nanostructures. Such nanostructures and methods of making are disclosed in U.S. Appl. Publ. No. 2020/0325396.

In some embodiments, the nanostructure composition comprises core-shell nanostructures that have been surface treated with zinc acetate and zinc fluoride. In some embodiments, the present disclosure provides a nanostructure composition comprising InP/ZnSe core-shell nanostructures. In some embodiments, the ZnSe shell has a thickness of between about 0.01 nm and about 5 nm. In some embodiments, the nanostructure is a quantum dot. Such nanostructures and methods for making are disclosed in U.S. Appl. Publ. No. 20210013377.

In some embodiments, the nanostructure composition comprises ZnSe₁₋ₓTeₓ alloy nanocrystals with one or more shell layers, wherein 0>x>1. In some embodiments, nanostructures comprise a core surrounded by at least one shell, wherein the core comprises ZnSe₁₋ₓTeₓ, wherein 0<x<1, wherein the at least one shell is selected from the group consisting of ZnS, ZnSe, ZnTe, and alloys thereof, and wherein the full width at half maximum (FWHM) of the nanostructure is about 20 nm to about 30 nm. Such nanostructures and methods of making are disclosed in U.S. Appl. Publ. No. 20210047563.

In some embodiments, nanostructures comprise a nanocrystal core and at least one shell, wherein at least one shell comprises at least one metal fluoride of formula (I): MF₄ (I) wherein: M=Zr, Hf, or Ti. In some embodiments, the nanostructures comprise: (a) a core comprising ZnSe, at least one shell comprising ZnS, and at least one shell comprising HfF₄; or (b) a core comprising ZnSe₁₋ₓTeₓ, wherein 0<x<1, at least one shell comprising ZnSe, and at least one shell comprising ZnS, and at least one shell comprising HfF₄. Such nanostructures and methods of making are disclosed in U.S. Appl. Publ. No. 2021/0277307.

In some embodiments, the nanostructure comprises a core surrounded by at least one shell, wherein the core comprises ZnSe₁₋ₓTeₓ, wherein 0<x<1, wherein the at least one shell comprises ZnS or ZnSe, and wherein the full width at half maximum (FWHM) of the nanostructure is between about 10 nm and about 30 nm. In some embodiments, the nanostructures are ZnSe₁₋ₓTeₓ/ZnSe/ZnS core/shell nanostructures. Such nanostructures and methods of making are disclosed in U.S. Appl. Publ. No. 20190390109.

In some embodiments, the nanostructures comprise nanocrystal core; and at least one shell disposed on the core, wherein at least one shell comprises ZnS and fluoride. In some embodiments, nanostructures comprise: a core comprising ZnSe, and at least one shell comprising ZnS and ZnF₂; a core comprising ZnSe, at least one shell comprising ZnSe, and at least one shell comprising ZnS and ZnF₂; a core comprising ZnSe₁₋ₓTeₓ, wherein 0<x<1, and at least one shell comprising ZnS and ZnF₂; or a core comprising ZnSe₁₋ₓTeₓ, wherein 0<x<1, at least one shell comprising ZnSe, and at least one shell comprising ZnS and ZnF₂. Such nanostructures and methods of making are disclosed in U.S. Appl. Publ. No. 2021/0009900.

In some embodiments, the nanostructures comprise at least one fluoride containing ligand bound to the surface of the nanostructure; wherein the fluoride containing ligand is selected from the group consisting of a fluorozincate, tetrafluoroborate, and hexafluorophosphate; or fluoride anions bound to the surface of the nanostructure; and wherein the nanostructure composition exhibits a photoluminescence quantum yield of between about 70% and about 90%. Such nanostructures and methods of making are disclosed in U.S. Appl. Publ. No. 2020/0299575.

In some embodiments, the nanostructures comprise Ag, In, Ga, and S (AIGS). In some embodiments, the nanostructures have a peak emission wavelength (PWL) in the range of 480-545 nm, wherein at least about 80% of the emission is band-edge emission, and wherein the nanostructures exhibit a quantum yield (QY) of 80-99.9%. Such nanostructures and methods of making are disclosed in U.S. Pat. No. 10,927,294.

In some embodiments, the nanostructures comprise at least one poly(alkylene oxide) ligand bound to the surface of the nanostructures. Such ligands are disclosed in U.S. Pat. No. 11,041,071.

### Films, Devices and Uses

A population of the nanostructures are embedded in UV-cured monomers that forms a film. This film may be used in production of a nanostructure phosphor, and/or incorporated into a device, e.g., an LED, backlight, downlight, or other display or lighting unit or an optical filter. Exemplary phosphors and lighting units can, e.g., generate a specific color light by incorporating a population of nanostructures with an emission maximum at or near the desired wavelength or a wide color gamut by incorporating two or more different populations of nanostructures having different emission maxima. A variety of suitable matrices are known in the art. See, e.g., U.S. Pat. No. 7,068,898 and U.S. Patent Application Publication Nos. 2010/0276638, 2007/0034833, and 2012/0113672. Exemplary nanostructure phosphor films, LEDs, backlighting units, etc. are described, e.g., in U.S. Patent Application Publications Nos. 2010/0276638, 2012/0113672, 2008/0237540, 2010/0110728, and 2010/0155749 and U.S. Pat. Nos. 7,374,807, 7,645,397, 6,501,091, and 6,803,719.

In some embodiments, the nanostructure films are used to form display devices. As used herein, a display device refers to any system with a lighting display. Such devices include, but are not limited to, devices encompassing a liquid crystal display (LCD), televisions, computers, mobile phones, smart phones, personal digital assistants (PDAs), gaming devices, electronic reading devices, digital cameras, and the like.

In some embodiments, the present disclosure provides a nanostructure molded article comprising:

(a) a first conductive layer;

(b) a second conductive layer; and

(c) a nanostructure layer between the first conductive layer and the second conductive layer, wherein the nanostructure layer comprises a population of nanostructures embedded in one or more UV-cured monomers.

In some embodiments, the present disclosure provides a nanostructure film comprising:

(a) at least one population of nanostructures; and

(b) at least one UV-cured monomer.

As used herein, the term “embedded” is used to indicate that the nanostructures are enclosed or encased within the one or more UV-cured monomers. In some embodiments, the nanostructures are uniformly distributed throughout the one or more UV-cured monomers. In some embodiments, the nanostructures are distributed according to an application-specific uniformity distribution function.

The present disclosure provides solvent-based nanostructure formulations comprising one or more UV-curable monomers and a photoinitiator. After film deposition, the nanostructure/monomer film may be cross-linked by UV illumination. Unexpectedly, despite the insulating nature of the polyacrylate network, the UV-cross-linked nanostructure film results in functional electroluminescent devices with high efficiency and luminance. The devices with UV-cross-linked nanostructure films have a prolonged operating lifetime. The UV-curable nanostructure film can be patterned by use of a photomask and suitable washing conditions to remove the non-illuminated segments.

A nanostructure film in QD-LEDs can undergo structural changes during device fabrication or operation which can affect the device performance. For example, solution-deposition of layers on top of the QDs can dissolve and remove nanostructures or their ligands, which will result in loss of luminescence. Thermal annealing of devices can facilitate interlayer diffusion which may introduce leakage pathways. Application of an electric field can result in ion dissociation and migration. Suppression of such structural changes through formation of a cross-linked network between or around the QDs improves the stability of QD-LEDs.

Fabrication of displays with electroluminescent QDs requires the formation of pixel patterns. Inkjet printing has slow throughput at high resolution and does not achieve the fine feature sizes, e.g. <5 μm, required for microdisplays for AR/VR application. Several photolithographic approaches for QD pattern formation for electroluminescence have been reported, albeit none with satisfying performance. Mixing QDs with photoresist results in high operating voltage due to the low QD loadings used (10-40 wt %) and in low efficiency due to poor compatibility between photoresist and QDs, as well as harsh development conditions using strong bases. Lift-off approaches with a photoresist layer that is separate from the QDs do not introduce insulating material to the QD film but introduce additional process steps and still result in poor efficiency and poor film uniformity due to the development conditions. Additives like photoacid generators or bis(azide) crosslinkers that modify ligand chemistry on the QD surface upon UV illumination seem promising with respect to simple processing and small additive loading, but suffer from efficiency losses for materials that rely on surface passivation by ligands, i.e. non-giant shell QDs. The present invention overcomes these deficiencies.

In some embodiments, the nanostructure film comprises one or more UV-cured monomers. In some embodiments, the one or more UV-cured monomers are UV-cured acrylates. In some embodiments, the UV-cured acrylates are selected from poly(methyl (meth)acrylate), poly(ethylene glycol phenyl (meth)acrylate), poly(di(ethylene glycol) methyl ether (meth)acrylate), poly(diethylene glycol monoethyl ether acrylate), poly(ethylene glycol methyl ether (meth)acrylate), poly(1,3-butylene glycol di(meth)acrylate), poly(polyethylene glycol di(meth)acrylate), poly(1,6-hexanediol diacrylate), poly(isobornyl acrylate), poly(tetrahydrofurfuryl acrylate), poly(lauryl acrylate), poly(tricyclodecane dimethanol diacrylate), poly(glycerol triacrylate), poly(1,1,1-trimethylolpropane triacrylate), poly(pentaerythritol tetraacrylate), poly(bistrimethylolpropane tetraacrylate), poly(dipentaerythritol pentaacrylate), poly(pentaerythritol triacrylate), poly(pentaerythritol tetracrylate), poly(trimethylolpropane triacrylate), poly(dipentaerythritol pentaacrylate ester), poly(isobornyl methacrylate), poly(tetrahydrofurfuryl methacrylate), poly(lauryl methacrylate), poly(tricyclodecane dimethanol dimethacrylate), poly(glycerol trimethacrylate), poly(1,1,1-trimethylolpropane trimethacrylate), poly(pentaerythritol tetramethacrylate), poly(bistrimethylolpropane tetramethacrylate), poly(dipentaerythritol pentamethacrylate), poly(pentaerythritol trimethacrylate), poly(pentaerythritol tetramethcrylate), poly(trimethylolpropane trimethacrylate), poly(dipentaerythritol pentamethacrylate ester), poly(1,6-hexanediol dimethacrylate), poly(1,4-butanediol diacrylate), poly(1,9-nonanediol diacrylate), poly(1,4-butanediol dimethacrylate), and poly(1,9-nonanediol dimethacrylate), or combinations thereof.

In some embodiments, the nanostructure film comprises between about 1 wt % and about 25 wt % of one or more UV-cured monomers. In some embodiments, the nanostructure film comprises between about 1 wt % and about 5 wt %, about 1 wt % and about 10 wt %, about 1 wt % and about 15 wt %, about 1 wt % and about 20 wt %, about 1 wt % and about 25 wt %, about 5 wt % and about 10 wt %, about 5 wt % and about 15 wt %, about 5 wt % and about 20 wt %, about 5 wt % and about 25 wt %, about 10 wt % and about 15 wt %, about 10 wt % and about 20 wt %, about 10 wt % and about 25 wt %, about 15 wt % and about 20 wt %, about 15 wt % and about 25 wt %, or about 20 wt % and about 25 wt % of one or more UV-cured monomers.

In some embodiments, the nanostructure film comprises nanostructures and UV-cured monomers, wherein the weight ratio of nanostructures to UV-cured monomers is between about 20:1 and about 1.5:1. In some embodiments, the nanostructure film comprises nanostructures and UV-cured monomers, wherein the weight ratio of nanostructures to UV-cured monomers is between about 20:1 and about 1.5:1, about 15:1 and about 1.5:1, about 10:1 and about 1.5:1, about 5:1 and about 1.5:1, about 20:1 and about 5:1, about 15:1 and about 5:1, about 10:1 and about 5:1, about 20:1 and about 10:1, about 15:1 and about 10:1, or about 20:1 and about 15:1.

In some embodiments, the nanostructure film comprises between about 60 wt % and about 95 wt % nanostructures. In some embodiments, the nanostructure film comprises between about 60 wt % and about 70%, about 60 wt % and about 75%, about 60 wt % and about 80%, about 60 wt % and about 85%, about 60 wt % and about 90%, about 70 wt % and about 75%, about 70 wt % and about 80%, about 70 wt % and about 85%, about 70 wt % and about 90%, about 70 wt % and about 95%, about 75 wt % and about 80%, about 75 wt % and about 85%, about 75 wt % and about 90%, about 75 wt % and about 95%, about 80 wt % and about 85%, about 80 wt % and about 90%, about 80 wt % and about 95%, about 85 wt % and about 90%, about 85 wt % and about 95%, or about 90% and about 95% nanostructures.

In some embodiments, the nanostructure film further comprises one or more barrier layers immediately adjacent to the nanostructure film that have low oxygen and moisture permeability and protect the nanostructures from degradation.

In some embodiments, the nanostructure film is formed from a solution comprising one or more photoinitiators. In some embodiments, the photoinitiator is a triazine-based compound, an acetophenone-based compound, a benzophenone-based compound, a thioxanthone-based compound, a benzoin-based compound, an oxime-based compound, or a combination thereof.

Examples of the triazine-based compound include 2,4,6-trichloro-s-triazine, 2-phenyl-4,6-bis(trichloro methyl)-s-triazine, 2-(3′,4′-dimethoxy styryl)-4,6-bis(trichloro methyl)-s-triazine, 2-(4′-methoxy naphthyl)-4,6-bis(trichloro methyl)-s-triazine, 2-(p-methoxy phenyl)-4,6-bis(trichloro methyl)-s-triazine, 2-(p-tolyl)-4,6-bis(trichloro methyl)-s-triazine, 2-biphenyl-4,6-bis(trichloro methyl)-s-triazine, 2,4-bis(trichloro methyl)-6-styryl-s-triazine, 2-(naphthol-yl)-4,6-bis(trichloro methyl)-s-triazine, 2-(4-methoxy naphthol-yl)-4,6-bis(trichloro methyl)-s-triazine, 2,4-bis(trichloro methyl) (piperonyl)-s-triazine, or 2,4-bis(trichloro methyl)-6-(4′-methoxy styryl)-s-triazine.

Examples of the acetophenone-based include 2,2′-diethoxy acetophenone, 2,2′-dibutoxy acetophenone, 2-hydroxy-2-methyl propinophenone, p-t-butyl trichloro acetophenone, p-t-butyl dichloro acetophenone, 4-chloro acetophenone, 2,2′-dichloro-4-phenoxy acetophenone, 2-methyl-1-(4-(methylthio)phenyl)-2-morpholino propan-1-one, and 2-benzyl-2-dimethyl amino-1-(4-morpholino phenyl)-butan-1-one.

Examples of the benzophenone-based compound include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-dichloro benzophenone, and 3,3′-dimethyl-2-methoxy benzophenone.

Examples of the thioxanthone-based compound include thioxanthone, 2-methyl thioxanthone, 2-isopropyl thioxanthone, 2,4-diethyl thioxanthone, 2,4-diisopropyl thioxanthone, and 2-chloro thioxanthone.

Examples of the benzoin-based compound include benzoin, benzoin methyl ether, benzoin ethyl ether, benzoin isopropyl ether, benzoin isobutyl ether, and benzyl dimethyl ketal.

Examples of the oxime-based compound include 2-(o-benzoyloxime)-1-[4-(phenylthio)phenyl]-1,2-octandione and 1-(o-acetyloxime)-1-[9-ethyl-6-(2-methylbenzoyl)-9H-carbazol-3-yl]ethanone.

The photoinitiator may also be a carbazole-based compound, a diketone compound, a sulfonium borate-based compound, a diazo-based compound, a biimidazole-based compound, and the like, in addition to the photoinitiator.

In some embodiments, the photoinitiator is 2,4,6-trimethylbenzoyldi-phenylphosphinate (TPO-L).

In some embodiments, the nanostructure film is formed from a solution comprising between about 0.05 wt % to about 0.5 wt % photoinitiator with respect to the weight of the one or more UV-curable monomers present in the solution. In some embodiments, the nanostructure film is formed from a solution comprising between about 0.05 wt % and about 0.1 wt %, about 0.05 wt % and about 0.2 wt %, about 0.05 wt % and about 0.3 wt %, between about 0.05 wt % and about 0.4 wt %, about 0.05 wt % and about 0.5 wt %, about 0.1 wt % and about 0.2 wt %, about 0.1 wt % and about 0.3 wt %, about 0.1 wt % and about 0.4 wt %, about 0.1 wt % and about 0.5 wt %, about 0.2 wt % and about 0.3 wt %, about 0.2 wt % and about 0.4 wt %, about 0.2 wt % and about 0.5 wt %, about 0.3 wt % and about 0.4 wt %, about 0.3 wt % and about 0.5 wt %, or 0.4 wt % and about 0.5 wt % photoinitiator with respect to the weight of the one or more UV-curable monomers present in the solution.

In some embodiments, a nanostructure film can be formed by mixing the composition comprising the nanostructures, the one or more UV-curable monomers, and a solvent (e.g., photoresist) and casting the nanostructure composition mixture on a substrate.

In some embodiments, the nanostructure film has a photoluminescent quantum yield (QY) of between about 35% and about 50%, about 35% and about 60%, about 35% and about 70%, about 35% and about 80%, about 35% and about 90%, about 35% and about 100%, about 50% and about 60%, about 50% and about 70%, about 50% and about 80%, about 50% and about 90%, about 50% and about 100%, about 60% and about 70%, about 60% and about 80%, about 60% and about 90%, about 60% and about 100%, about 70% and about 80%, about 70% and about 90%, about 70% and about 100%, about 80% and about 90%, about 80% and about 100%, or about 90% and about 100%.

In some embodiments, the population of nanostructures is used to form a nanostructure molded article. In some embodiments, the nanostructure molded article is a liquid crystal display (LCD) or a light emitting diode (LED). In some embodiments, the nanostructure composition is used to form the emitting layer of an illumination device. The illumination device can be used in a wide variety of applications, such as flexible electronics, touchscreens, monitors, televisions, cellphones, and any other high definition displays. In some embodiments, the illumination device is a light emitting diode or a liquid crystal display. In some embodiments, the illumination device is a quantum dot light emitting diode (QLED). An example of a QLED is disclosed in U.S. patent application No. 15/824,701, which is incorporated herein by reference in its entirety. In some embodiments, the core-shell nanostructures are InP/ZnSe or ZnTeSe/ZnSe/ZnS. In some embodiments, the molded article does not comprise a separate barrier layer to protect the nanostructures from oxygen and/or moisture.

In some embodiments, the present disclosure provides an illumination device comprising:

(a) a first conductive layer;

(b) a second conductive layer; and

(c) an emitting layer between the first conductive layer and the second conductive layer, wherein the emitting layer comprises at least one population of nanostructures and one or more UV-cured monomers.

In some embodiments, the core-shell nanostructures are CdSe/ZnSe, ZnTeSe/ZnSe/ZnS, or InP/ZnSe.

In some embodiments, the emitting layer is a nanostructure film.

In some embodiments, the illumination device comprises a first conductive layer, a second conductive layer, and an emitting layer, wherein the emitting layer is arranged between the first conductive layer and the second conductive layer. In some embodiments, the emitting layer is a thin film comprising one or more populations of nanostructures and one or more UV-cured monomers.

In some embodiments, the illumination device comprises additional layers between the first conductive layer and the second conductive layer such as a hole injection layer, a hole transport layer, and an electron transport layer. In some embodiments, the hole injection layer, the hole transport layer, and the electron transport layer are thin films. In some embodiments, the layers are stacked on a substrate.

When voltage is applied to the first conductive layer and the second conductive layer, holes injected at the first conductive layer move to the emitting layer via the hole injection layer and/or the hole transport layer, and electrons injected from the second conductive layer move to the emitting layer via the electron transport layer. The holes and electrons recombine in the emitting layer to generate excitons. In some embodiments, the hole transport layer comprises poly[(9,9-dioctylfluorenyl-2,7-diyl)-co-(4,4′-(N-(4-sec-butylphenyl)diphenylamine)] (TFB).

The substrate can be any substrate that is commonly used in the manufacture of illumination devices. In some embodiments, the substrate is a transparent substrate, such as glass. In some embodiments, the substrate is a flexible material such as polyimide, or a flexible and transparent material such as polyethylene terephthalate. In some embodiments, the substrate has a thickness of between about 0.1 mm and about 2 mm. In some embodiments, the substrate is a glass substrate, a plastic substrate, a metal substrate, or a silicon substrate.

In some embodiments, a first conductive layer is disposed on the substrate. In some embodiments, the first conductive layer is a stack of conductive layers. In some embodiments, the first conductive layer has a thickness between about 50 nm and about 250 nm. In some embodiments, the first conductive layer is deposited as a thin film using any known deposition technique, such as, for example, sputtering or electron-beam evaporation. In some embodiments, the first conductive layer comprises indium tin oxide (ITO), indium zinc oxide (IZO), tin dioxide (SnO₂), zinc oxide (ZnO), magnesium (Mg), aluminum (Al), aluminum-lithium (Al—Li), calcium (Ca), magnesium-indium (Mg—In), magnesium-silver (Mg—Ag), silver (Ag), gold (Au), or mixtures thereof. In some embodiments, the first conductive layer is an anode.

In some embodiments, additional layers can be sandwiched between a first conductive layer and a second conductive layer. In some embodiments, the first conductive layer acts as the anode of the device while the second conductive layer acts as the cathode of the device. In some embodiments, the second conductive layer is a metal, such as aluminum. In some embodiments, the second conductive layer has a thickness between about 100 nm and about 150 nm. In some embodiments, the second conductive layer represents a stack of conductive layers. For example, a second conductive layer can include a layer of silver sandwiched between two layers of ITO (ITO/Ag/ITO).

In some embodiments, the second conductive layer comprises indium tin oxide (ITO), an alloy of indium oxide and zinc (IZO), titanium dioxide, tin oxide, zinc sulfide, silver (Ag), or mixtures thereof.

In some embodiments, the illumination device further comprises a semiconductor polymer layer. In some embodiments, the semiconductor polymer layer acts as a hole injection layer. In some embodiments, the semiconductor polymer layer is deposited on the first conductive layer. In some embodiments, the semiconductor polymer layer is deposited by vacuum deposition, spin-coating, printing, casting, slot-die coating, or Langmuir-Blodgett (LB) deposition. In some embodiments, the semiconductor polymer layer has a thickness between about 20 nm and about 60 nm.

In some embodiments, the semiconductor polymer layer comprises copper phthalocyanine, 4,4¹,4″-tris[(3-methylphenyl)phenylamino] triphenylamine (m-MTDATA), 4,4′,4″-tris(diphenylamino) triphenylamine (TDATA), 4,4′,4″-tris[2-naphthyl(phenyl)amino]triphenylamine (2T-NATA), polyaniline/dodecylbenzenesulfonic acid, poly(3,4-ethylenedioxythiophene)/polystyrene sulfonate) (PEDOT/PSS), polyaniline/camphor sulfonic acid, or polyaniline/poly(4-styrenesulfonate).

In some embodiments, the illumination device further comprises transport layers to facilitate the transport of electrons and holes affected by the generated electric field between the first conductive layer and the second conductive layer. In some embodiments, the illumination device further comprises a first transport layer associated with the first conductive layer. In some embodiments, the first transport layer acts as a hole transport layer (and an electron and/or exciton blocking layer). In some embodiments, the first transport layer is deposited on the first conductive layer. In some embodiments, the first transport layer is deposited on the semiconductor polymer layer. In some embodiments, the first transport layer has a thickness between about 20 nm and about 50 nm. In some embodiments, the first transport layer is substantially transparent to visible light.

In some embodiments, the first transport layer comprises a material selected from the group consisting of an amine, a triarylamine, a thiophene, a carbazole, a phthalocyanine, a porphyrin, or a mixture thereof. In some embodiments, the first transport layer comprises N,N′-di(naphthalen-1-yl)-N,N′-bis(4-vinylphenyl)-4,4′-diamine, poly[(9,9-dioctylfluorenyl-2,7-diyl)-co-(4,4′-(N-(4-sec-butylphenyl))diphenylamine)], and poly(9-vinylcarbazole).

In some embodiments, the illumination device further comprises a second transport layer. In some embodiments, the second transport layer acts as an electron transport layer (and a hole and/or exciton blocking layer). In some embodiments, the second transport layer contacts the emitting layer. In some embodiments, the second transport layer is arranged between the emitting layer and the second conductive layer. In some embodiments, the second transport layer has a thickness between about 20 nm and about 50 nm. In some embodiments, the second transport layer is substantially transparent to visible light.

In some embodiments, the second transport layer is an electron transport layer.

The roles of the first transport layer and the second transport layer are reversed when the polarity of the first conductive layer and the second conductive layer are reversed.

In some embodiments, the illumination device comprises at least one electron transport layer. In some embodiments, the illumination device is a quantum dot light emitting diode.

In some embodiments, the electron transport layer has a thickness between about 20 nm and about 50 nm. In some embodiments, the electron transport layer has a thickness between about 20 nm and about 50 nm, about 20 nm and about 40 nm, about 20 nm and about 30 nm, about 30 nm and about 50 nm, about 30 nm and about 40 nm, or about 40 nm and about 50 nm.

In some embodiments, the electron transport layer comprises zinc oxide.

In some embodiments, the electron transport layer comprises zinc magnesium oxide.

In some embodiments, the illumination device has an external quantum efficiency (EQE) of between about 2% and about 3%, about 2% and about 4%, about 2% and about 5%, about 2% and about 6%, about 2% and about 7%, about 2% and about 8%, about 2% and about 9%, about 2% and about 10%, about 3% and about 4%, about 3% and about 5%, about 3% and about 6%, about 3% and about 7%, about 3% and about 8%, about 3% and about 9%, about 3% and about 10%, about 4% and about 5%, about 4% and about 6%, about 4% and about 7%, about 4% and about 8%, about 4% and about 9%, about 4% and about 10%, about 5% and about 6%, about 5% and about 7%, about 5% and about 8%, about 5% and about 9%, about 5% and about 10%, about 6% and about 7%, about 6% and about 8%, about 6% and about 9%, about 6% and about 10%, about 7% and about 8%, about 7% and about 9%, about 7% and about 10%, about 8% and about 9%, about 8% and about 10%, or about 9% and about 10%.

In some embodiments, the illumination device has a maximum luminance of between about 4,000 cd/m² and about 6,000 cd/m², about 4,000 cd/m² and about 9,000 cd/m², about 4,000 cd/m² and about 12,000 cd/m², about 6,000 cd/m² and about 9,000 cd/m², about 6,000 cd/m² and about 12,000 cd/m², or about 9,000 cd/m² and about 12,000

In some embodiments, the illumination device has a lifetime at 1,000 nits of between about 8.5 h and about 20.5 h, about 6 h and about 10 h, about 6 h and about 13 h, about 6 h and about 16 h, about 6 h and about 20 h, about 6 h and about 24 h, about 10 h and about 13 h, about 10 h and about 16 h, about 10 h and about 20 h, about 10 h and about 24 h, about 13 h and about 16 h, about 13 h and about 20 h, about 13 h and about 24 h, about 16 h and about 20 h, about 16 h and about 24 h, or about 20 h and about 24 h.

In some embodiments, the illumination device has a lifetime at 100 nits of between about 500 h to about 1,300 h, about 400 h to about 700 h, about 400 h to about 900 h, about 400 h to about 1,300 h, about 400 h to about 1,600 h, about 700 h to about 900 h, about 700 h to about 1,300 h, about 700 h to about 1,600 h, about 900 h to about 1,300 h, about 900 h to about 1,600 h, or about 1,300 h to about 1,600 h.

In some embodiments, the nanostructure film is incorporated into a glass LCD display device. A LCD display device can include a nanostructure film formed directly on a light guide plate (LGP) without necessitating an intermediate substrate or barrier layer. In some embodiments, a nanostructure film can be a thin film. In some embodiments, a nanostructure film can have a thickness of 500 μm or less, 100 μm or less, or 50 μm or less. In some embodiments, a nanostructure film is a thin film having a thickness of about 15 μm or less. In some embodiments, the core-shell nanostructures are CdSe/ZnSe, ZnTeSe/ZnSe/ZnS, or InP/ZnSe.

A LGP can include an optical cavity having one or more sides, including at least a top side, comprising glass. Glass provides excellent resistance to impurities including moisture and air. Moreover, glass can be formed as a thin substrate while maintaining structural rigidity. Therefore, a LGP can be formed at least partially of a glass surface to provide a substrate having sufficient barrier and structural properties.

In some embodiments, a nanostructure film can be formed on a LGP. In some embodiments, the nanostructure film comprises one or more populations of nanostructures and one or more UV-cured monomers. A nanostructure film can be formed on a LGP by any method known in the art, such as wet coating, painting, spin coating, or screen printing. After deposition, the one or more UV-curable monomers of a nanostructure film can be cured. In some embodiments the one or more UV-curable monomers of a nanostructure film can be partially cured, further processed and then finally cured. The nanostructure films can be deposited as one layer or as separate layers, and the separate layers can comprise varying properties. The width and height of the nanostructure films can be any desired dimensions, depending on the size of the viewing panel of the display device. For example, the nanostructure films can have a relatively small surface area in small display device embodiments such as watches and phones, or the nanostructure films can have a large surface area for large display device embodiments such as TVs and computer monitors.

In some embodiments, an optically transparent substrate is formed on the nanostructure film by any method known in the art, such as vacuum deposition, vapor deposition, or the like. An optically transparent substrate can optionally be configured to provide environmental sealing to the underlying layers and/or structures of the nanostructure film. In some embodiments, light blocking elements can be included in the optically transparent substrate. In some embodiments, light blocking elements can be included in a second polarizing filter, which can be positioned between the substrate and the nanostructure film. In some embodiments, light blocking elements can be dichroic filters that, for example, can reflect the primary light (e.g., blue light, UV light, or combination of UV light and blue light) while transmitting the secondary light. Light blocking elements can include specific UV light filtering components to remove any unconverted UV light from the red and green sub-pixels, and/or the UV light from the blue sub-pixels.

In some embodiments, the nanostructure films are incorporated into display devices by “on-chip” placements. As used herein, “on-chip” refers to placing nanostructures into an LED cup. In some embodiments, the nanostructures are dissolved in a resin or a fluid to fill the LED cup. In some embodiments, the LED cup does not further comprise a barrier layer to protect the nanostructures from oxygen and/or moisture.

In some embodiments, the nanostructures are incorporated into display devices by “near-chip” placements. As used herein, “near-chip” refers to coating the top surface of the LED assembly with nanostructures such that the outgoing light passes through the nanostructure film.

In some embodiments, the present invention provides a display device comprising:

(a) a display panel to emit a first light;

(b) a backlight unit configured to provide the first light to the display panel; and

(c) a color filter comprising at least one pixel region comprising a color conversion layer.

In some embodiments, the color filter comprises at least 1, 2, 3, 4, 5, 6, 7, 8, 9, or 10 pixel regions. In some embodiments, when blue light is incident on the color filter, red light, white light, green light, and/or blue light may be respectively emitted through the pixel regions. In some embodiments, the color filter is described in U.S. Patent Appl. Publication No. 2017/153366.

In some embodiments, each pixel region includes a color conversion layer. In some embodiments, a color conversion layer comprises nanostructures described herein configured to convert incident light into light of a first color. In some embodiments, the color conversion layer comprises nanostructures described herein configured to convert incident light into blue light.

In some embodiments, the display device comprises 1, 2, 3, 4, 5, 6, 7, 8, 9, or 10 color conversion layers. In some embodiments, the display device comprises one color conversion layer comprising the nanostructures described herein. In some embodiments, the display device comprises two color conversion layers comprising the nanostructures described herein. In some embodiments, the display device comprises three color conversion layers comprising the nanostructures described herein. In some embodiments, the display device comprises four color conversion layers comprising the nanostructures described herein. In some embodiments, the display device comprises at least one red color conversion layer, at least one green color conversion layer, and at least one blue color conversion layer.

In some embodiments, the color conversion layer has a thickness between about 3 μm and about 10 μm, about 3 μm and about 8 μm, about 3 μm and about 6 μm, about 6 μm and about 10 μm, about 6 μm and about 8 μm, or about 8 μm and about 10 μm. In some embodiments, the color conversion layer has a thickness between about 3 μm and about 10 μm.

### Methods of Making Films

The present disclosure provides methods of making patterned films comprising nanostructures and one or more UV-cured monomers. In some embodiments, the method of making the patterned film comprises:

(a) depositing onto the substrate a solution comprising the nanostructures, one or more UV-curable monomers, a photoinitiator, and one or more solvents, wherein the weight ratio of the nanostructures to the one or more UV-curable monomers is from about 20:1 to about 1.5:1;

(b) evaporating the one or more solvents to give a film comprising the nanostructures, one or more UV-curable monomers, and a photoinitiator;

(c) applying a photomask to the substrate obtained in (b);

(d) irradiating the substrate with ultraviolet radiation;

(e) removing the photomask; and

(f) washing the substrate with one or more solvents to provide the patterned film.

In some embodiments, the one or more UV-curable monomers are UV-curable acrylate monomers. In some embodiments, the UV-curable acrylate monomers are selected from methyl (meth)acrylate, ethylene glycol phenyl (meth)acrylate, di(ethylene glycol) methyl ether (meth)acrylate, diethylene glycol monoethyl ether acrylate, ethylene glycol methyl ether (meth)acrylate, 1,3-butylene glycol di(meth)acrylate, polyethylene glycol di(meth)acrylate, and 1,6-hexanediol diacrylate, or combinations thereof

In some embodiments, the film obtained in (b) comprises between about 1 wt % and about 25 wt % of one or more UV-curable monomers. In some embodiments, the film obtained in (b) comprises between about 1 wt % and about 5 wt %, about 1 wt % and about 10 wt %, about 1 wt % and about 15 wt %, about 1 wt % and about 20 wt %, about 1 wt % and about 25 wt %, about 5 wt % and about 10 wt %, about 5 wt % and about 15 wt %, about 5 wt % and about 20 wt %, about 5 wt % and about 25 wt %, about 10 wt % and about 15 wt %, about 10 wt % and about 20 wt %, about 10 wt % and about 25 wt %, about 15 wt % and about 20 wt %, about 15 wt % and about 25 wt %, or about 20 wt % and about 25 wt % of one or more UV-curable monomers.

In some embodiments, the film obtained in (b) comprises nanostructures and UV-curable monomers, wherein the weight ratio of nanostructures to UV-curable monomers is between about 20:1 and about 1.5:1. In some embodiments, the film obtained in (b) comprises nanostructures and UV-curable monomers, wherein the weight ratio of nanostructures to UV-curable monomers is between about 20:1 and about 1.5:1, about 15:1 and about 1.5:1, about 10:1 and about 1.5:1, about 5:1 and about 1.5:1, about 20:1 and about 5:1, about 15:1 and about 5:1, about 10:1 and about 5:1, about 20:1 and about 10:1, about 15:1 and about 10:1, or about 20:1 and about 15:1.

In some embodiments, the film obtained in (b) comprises between about 60 wt % and about 95 wt % nanostructures. In some embodiments, the solution comprises between about 60 wt % and about 70%, about 60 wt % and about 75%, about 60 wt % and about 80%, about 60 wt % and about 85%, about 60 wt % and about 90%, about 70 wt % and about 75%, about 70 wt % and about 80%, about 70 wt % and about 85%, about 70 wt % and about 90%, about 70 wt % and about 95%, about 75 wt % and about 80%, about 75 wt % and about 85%, about 75 wt % and about 90%, about 75 wt % and about 95%, about 80 wt % and about 85%, about 80 wt % and about 90%, about 80 wt % and about 95%, about 85 wt % and about 90%, about 85 wt % and about 95%, or about 90% and about 95% nanostructures.

Examples of solvents include toluene, benzene, xylene, ethanol, methanol, 1-propanol, 2-propanol, acetone, methyl ethyl ketone, methyl isobutyl ketone, ethyl acetate, tetrahydrofuran, chloroform, chlorobenzene, cyclohexane, hexane, heptane, octane, hexadecane, undecane, decane, dodecane, octadecane, tetradecane, butyl ether, dipropylene glycol monomethyl ether acetate (DPMA), polyglycidyl methacrylate (PGMA), diethylene glycol monoethyl ether acetate (EDGAC), propylene glycol methyl ether acetate (PGMEA), 1-tetralone, 3-phenoxytoluene, acetophenone, 1-methoxynaphthalene, n-octylbenzene, n-nonylbenzene, 4-methylanisole, n-decylbenzene, p-diisopropylbenzene, pentylbenzene, tetralin, cyclohexylbenzene, chloronaphthalene, 1,4-dimethylnaphthalene, 3-i sopropylbiphenyl, p-methylcumene, dipentylbenzene, o-diethylbenzene, m-diethylbenzene, p-diethylbenzene, 1,2,3,4-tetramethylbenzene, 1,2,3,5-tetramethylbenzene, 1,2,4,5-tetrametylbenzene, butylbenzene, dodecylbenzene, 1-methylnaphthalene, 1, 2, 4-tri chlorobenzene, diphenyl ether, diphenylmethane, 4-isopropylbiphenyl, benzyl benzoate, 1,2-bis(3,4-dimethylphenyl)ethane, 2-isopropylnaphthalene, dibenzyl ether, cyclododecene, butyl acetate, hexyl acetate, or combinations thereof.

The solvent may be evaporated by heating the substrate, placing the substrate under reduced pressure, or a combination thereof.

The photomask blocks portions of the deposited nanostructures and one or more UV-curable monomers from exposure to ultraviolet radiation. The photomask may take any shape appropriate to form a desired pattern on the substrate after irradiating with ultraviolet radiation and washing. In some embodiments, the shape of the photomask results in a pixel pattern after ultraviolet radiation and washing.

The substrate can be irradiated by any ultraviolet radiation source known in the art. Examples of sources of ultraviolet radiation include mercury vapor lamps, fluorescent lamps, and LED lamps. In some embodiments, the wavelength of ultraviolet radiation is about 365 nm. In some embodiments, the wavelength of ultraviolet radiation is about 253 nm.

In some embodiments, the irradiating in (d) is a dose of between about 500 mJ/cm² and about 550 mJ/cm². In some embodiments, the irradiating in (d) is a dose of between about 100 mJ/cm² and about 200 mJ/cm², about 100 mJ/cm² and about 300 mJ/cm², about 100 mJ/cm² and about 400 mJ/cm², about 100 mJ/cm² and about 500 mJ/cm², about 100 mJ/cm² and about 600 mJ/cm², about 100 mJ/cm² and about 700 mJ/cm², about 100 mJ/cm² and about 800 mJ/cm², about 100 mJ/cm² and about 900 mJ/cm², about 100 mJ/cm² and about 1000 mJ/cm², about 200 mJ/cm² and about 300 mJ/cm², about 200 mJ/cm² and about 400 mJ/cm², about 200 mJ/cm² and about 500 mJ/cm², about 200 mJ/cm² and about 600 mJ/cm², about 200 mJ/cm² and about 700 mJ/cm², about 200 mJ/cm² and about 800 mJ/cm², about 200 mJ/cm² and about 900 mJ/cm², about 200 mJ/cm² and about 1000 mJ/cm², about 300 mJ/cm² and about 400 mJ/cm², about 300 mJ/cm² and about 500 mJ/cm², about 300 mJ/cm² and about 600 mJ/cm², about 300 mJ/cm² and about 700 mJ/cm², about 300 mJ/cm² and about 800 mJ/cm², about 300 mJ/cm² and about 900 mJ/cm², about 300 mJ/cm² and about 1000 mJ/cm², about 400 mJ/cm² and about 500 mJ/cm², about 400 mJ/cm² and about 600 mJ/cm², about 400 mJ/cm² and about 700 mJ/cm², about 400 mJ/cm² and about 800 mJ/cm², about 400 mJ/cm² and about 900 mJ/cm², about 400 mJ/cm² and about 1000 mJ/cm², about 500 mJ/cm² and about 600 mJ/cm², about 500 mJ/cm² and about 700 mJ/cm², about 500 mJ/cm² and about 800 mJ/cm², about 500 mJ/cm² and about 900 mJ/cm², about 500 mJ/cm² and about 1000 mJ/cm², about 600 mJ/cm² and about 700 mJ/cm², about 600 mJ/cm² and about 800 mJ/cm², about 600 mJ/cm² and about 900 mJ/cm², about 600 mJ/cm² and about 1000 mJ/cm², about 700 mJ/cm² and about 800 mJ/cm², about 700 mJ/cm² and about 900 mJ/cm², about 700 mJ/cm² and about 1000 mJ/cm², about 800 mJ/cm² and about 900 mJ/cm², about 800 mJ/cm² and about 1000 mJ/cm², or about 900 mJ/cm² and about 1000 mJ/cm².

In some embodiments, the irradiating in (d) is a dose of about 530 mJ/cm². In some embodiments, the irradiating in (d) is a dose of about 50 mJ/cm², about 100 mJ/cm², about 150 mJ/cm², about 200 mJ/cm², about 250 mJ/cm², about 300 mJ/cm², about 350 mJ/cm², about 400 mJ/cm², about 450 mJ/cm², about 500 mJ/cm², about 550 mJ/cm², about 600 mJ/cm², about 650 mJ/cm², about 700 mJ/cm², about 750 mJ/cm², about 800 mJ/cm², about 850 mJ/cm², about 900 mJ/cm², about 950 mJ/cm², or about 1000 mJ/cm².

### EXAMPLES

Example 1

### UV-Cured HDDA QD Films with High QD Loadings

Here it is shown that formulations with high QD loadings in the range of 80 to 95 wt % (or 5 to 20 wt % acrylate) result in UV-curable QD films with good performance in electroluminescent devices. The acrylate formulation with high QD loading is not a fluid, therefore a non-reactive organic solvent that can be evaporated is used as a carrier for solution deposition. These formulations use PEG-based ligands on the QD surface to enhance dispersibility of QDs in acrylate monomers.

Table 1 demonstrates the impact of acrylate loading (specifically 1,6-hexanediol diacrylate, HDDA) in wt % relative to blue ZnTeSe/ZnSe/ZnS QDs on the solubility of the films after UV illumination (365 nm, 530-630 mJ/cm²). Films were drop-casted from toluene, dried, illuminated, and then soaked in toluene. With an HDDA loading under 5 wt %, the illuminated films dissolved in toluene. With HDDA loadings between 5 and 20 wt % the cured films were increasingly insoluble as judged by the low or absent intensity of luminescence in the toluene used for soaking the cured films. Furthermore, optimization of the amount of photoinitiator TPO-L (wt % relative to HDDA) resulted in a solid state quantum yield (QY) as good as in the control sample without acrylate or initiator.

TABLE 1

| ID | HDDA wt % | TPO-L wt % | Cured QY % | Toluene solubility |
|---|---|---|---|---|
| 1 | 0 | 0 | 49.5 | Soluble |
| 2 | 2.5 | 0.25 | - | Soluble |
| 3 | 5 | 0.25 | 35.3 | Partially insoluble |
| 4 | 7.5 | 0.25 | - | Mostly insoluble |
| 5 | 10 | 0.25 | 39.4 | Mostly insoluble |
| 6 | 10 | 0.1 | 51.6 | Completely insoluble |
| 7 | 10 | 0 | 53.4 | Partially insoluble |
| 8 | 20 | 0.25 | 38.3 | Completely insoluble |

### Example 2

### Electroluminescent Devices Comprising UV-Curable HDDA QD Films with High QD Loadings as Emissive Layer

The performance of UV-curable HDDA QD films with high QD loadings as emissive layers (EML) in electroluminescent devices (structure: ITO/PEDOT:PSS/SH112/QD/ZnMgO/LiF/Al) were tested. Polyacrylates are insulators and therefore it was expected that charge transport and injection into the QDs would be hindered. The J-V characteristics in Figs. lA and 1B confirm this effect: Current density decreases with increasing HDDA content, and the effect is more pronounced for a thicker EML, meaning the mobility in the crosslinked EML is lower.

Despite the lower current density, the devices were still functional. Unexpectedly, they have improved efficiency and lifetime, as shown in Table 2. External quantum efficiency (EQE) improved from 1.6-2.6% for EMLs without HDDA to 4.0-4.9% for EMLs with HDDA. The achieved maximum luminance (at 7 V, end of the sweep) was on the same order of magnitude for the crosslinked samples because the higher efficiency compensates the lower current density. The lifetime increased significantly with the UV treatment that initiates the crosslinking, for example almost an order of magnitude from 2.8 h to 20.1 h T50 at 1000 nits for the sample with 10 wt % HDDA. There was no trade-off in efficiency with this lifetime improvement.

TABLE 2

| | EML spin- | | UV treat. | | Max | Max L | T95 @ | T50 @ | T50 @ |
|---|---|---|---|---|---|---|---|---|---|
| EML | speed | | on EML | Device | EQE | (cd/m²) | 1K nits | 1K nits | 100 nits |
| Toluene | 1 | krpm-d | yes | 1 | 2.58% | 6151 | 2.97 | 11.68 | 736.9 |
| Ctrl, no | 1.5 | krpm-d | yes | 2 | 1.94% | 5573 | 2.34 | 8.95 | 564.4 |
| HDDA | 2 | krpm-d | yes | 3 | 1.58% | 7139 | 1.52 | 6.57 | 414.6 |
| | 2 | krpm-d | no | 4 | 1.62% | 5689 | 0.25 | 3.07 | 193.6 |
| Toluene | 1 | krpm-d | yes | 5 | 4.78% | 6572 | 1.61 | 14.54 | 917.4 |
| 7 wt % | 1.5 | krpm-d | yes | 6 | 4.81% | 7587 | 2.97 | 15.31 | 965.8 |
| HDDA | 2 | krpm-d | yes | 7 | 4.29% | 7434 | 4.9 | 17.06 | 1076.3 |
| | 2 | krpm-d | no | 8 | 4.12% | 8219 | 0.05 | 1.41 | 89.2 |
| Toluene | 1 | krpm-d | yes | 9 | 4.95% | 4068 | 0.73 | 8.58 | 541.2 |
| 10 wt % | 1.5 | krpm-d | yes | 10 | 4.69% | 6161 | 2.3 | 14.2 | 895.7 |
| HDDA | 2 | krpm-d | yes | 11 | 4.36% | 8635 | 5.05 | 20.14 | 1270.7 |
| | 2 | krpm-d | no | 12 | 4.00% | 8396 | 0.71 | 2.76 | 174.1 |

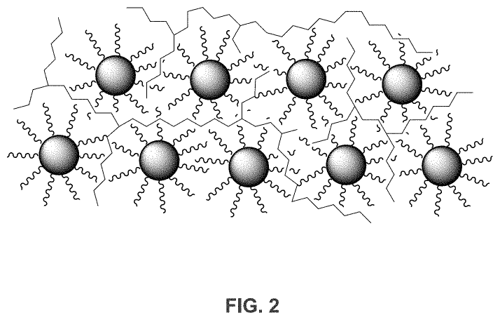

Without being bound by a particular theory, a hypothesized mechanism for the lifetime improvement is illustrated schematically in FIG. 2. The polymerization of HDDA in the QD film results in formation of a network around the QDs that restricts the movement of QDs and ligands. This prevents ligand desorption during the subsequent processing or during operation and therefore helps maintaining the surface passivation of the QDs.

The UV-induced immobilization of QDs also enables patterning with a photomask and pattern development by washing off the QD/HDDA mixture in the non-illuminated areas with a suitable solvent. A pixel pattern with well-defined, photoluminescent 100×300 μm features was formed using red InP/ZnSe/ZnS QDs with PEG ligands and 10 wt % HDDA. Ethanol was used to remove QD/HDDA from non-illuminated areas after UV exposure.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

The claims in the instant application are different than those of the parent application or other related applications. The Applicant therefore rescinds any disclaimer of claim scope made in the parent application or any predecessor application in relation to the instant application. The Examiner is therefore advised that any such previous disclaimer and the cited references that it was made to avoid, may need to be revisited. Further, the Examiner is also reminded that any disclaimer made in the instant application should not be read into or against the parent application.

All patents and published applications noted above are incorporated herein by reference in their entirety.

1. An ultraviolet (UV)-cured patterned film deposited on a substrate comprising from about 60 wt % to about 95 wt % nanostructures and one or more UV-cured monomers.

2. The film of claim 1, wherein the one or more UV-cured monomers are poly(methyl (meth)acrylate), poly(ethylene glycol phenyl (meth)acrylate), poly(di(ethylene glycol) methyl ether (meth)acrylate), poly(diethylene glycol monoethyl ether acrylate), poly(ethylene glycol methyl ether (meth)acrylate), poly(1,3-butylene glycol di(meth)acrylate), poly(polyethylene glycol di(meth)acrylate), poly(1,6-hexanediol diacrylate), poly(isobornyl acrylate), poly(tetrahydrofurfuryl acrylate), poly(lauryl acrylate), poly(tricyclodecane dimethanol diacrylate), poly(glycerol triacrylate), poly(1,1,1-trimethylolpropane triacrylate), poly(pentaerythritol tetraacrylate), poly(bistrimethylolpropane tetraacrylate), poly(dipentaerythritol pentaacrylate), poly(pentaerythritol triacrylate), poly(pentaerythritol tetracrylate), poly(trimethylolpropane triacrylate), poly(dipentaerythritol pentaacrylate ester), poly(isobornyl methacrylate), poly(tetrahydrofurfuryl methacrylate), poly(lauryl methacrylate), poly(tricyclodecane dimethanol dimethacrylate), poly(glycerol trimethacrylate), poly(1,1,1-trimethylolpropane trimethacrylate), poly(pentaerythritol tetramethacrylate), poly(bistrimethylolpropane tetramethacrylate), poly(dipentaerythritol pentamethacrylate), poly(pentaerythritol trimethacrylate), poly(pentaerythritol tetramethcrylate), poly(trimethylolpropane trimethacrylate), poly(dipentaerythritol pentamethacrylate ester), poly(1,6-hexanediol dimethacrylate), poly(1,4-butanediol diacrylate), poly(1,9-nonanediol diacrylate), poly(1,4-butanediol dimethacrylate), poly(1,9-nonanediol dimethacrylate), or combinations thereof.

3. The film of claim 1 or 2 claim 1, wherein the film further comprises one or more photoinitiators.

4. The film of any one of claims 1 3 claim 1, wherein the film is produced by (a) depositing onto the substrate a solution comprising the nanostructures, one or more UV-curable monomers, a photoinitiator, and one or more solvents, wherein the weight ratio of the nanostructures to the one or more UV-curable monomers is from about 20:1 to about 1.5:1; (b) evaporating the one or more solvents to give a film comprising the nanostructures, one or more UV-curable monomers, and a photoinitiator; (c) applying a photomask to the substrate; (d) irradiating the substrate with ultraviolet radiation; (e) removing the photomask; and (f) washing the substrate with one or more solvents to provide the patterned film.

5. The film of claim 4, wherein the weight ratio of the nanostructures to the one or more UV-curable monomers is from about 14:1 to about 6:1.

6. The film of claim 4, wherein the one or more UV-curable monomers are acrylate monomers.

7. The film of claim 6, wherein the acrylate monomer is 1,6-hexanediol diacrylate.

8. The film of claim 4, wherein the film obtained in (b) comprises from about 0.1 wt % to about 0.3 wt % photoinitiator relative to the total weight of the one of more UV-curable monomers.

9. The film of claim 4, wherein the photoinitiator is ethyl phenyl(2,4,6-trimethylbenzoyl)phosphinate (TPO-L).

10. The film of claim 4, wherein the irradiating in (d) is a dose of about 530 mJ/cm² of 365 nm ultraviolet radiation.

11. The film of claim 4, wherein the one or more solvents is toluene.

12. The film of claim 1, wherein the nanostructures are quantum dots.

13. The film of claim 1, wherein the nanostructures comprises polyethylene glycol-based ligands.

14. The film of claim 1, wherein the film is insoluble in toluene.

15. The film of claim 1, wherein the film has a quantum yield (QY) of from about 35% to about 50%.

16. An electroluminescent device comprising the film of claim 1.

17. The electroluminescent device of claim 16, wherein the device has a maximum external quantum efficiency (EQE) of from about 3.75% to about 5.25%.

18. The electroluminescent device of claim 16, wherein the device has a maximum luminance of from about 4,000 cd/m² to about 9,000 cd/m².

19. The electroluminescent device of claim 16, wherein the device has a lifetime at 1,000 nits of from about 8.5 h to about 20.5 h.

20. The electroluminescent device of claim 16, wherein the device has a lifetime at 100 nits of from about 500 h to about 1,300 h.

21. The electroluminescent device of claim 16, wherein the film pattern is a pixel pattern.
